(19) United States
(12) Patent Application Publication
(10) Pub. No.: US 2009/0170042 A1
(43) Pub. Date: Jul. 2, 2009

(54) EXPOSURE APPARATUS AND DEVICE MANUFACTURING METHOD

(75) Inventors: Tsuneo Kanda, Utsunomiya-shi (JP); Kazuhiro Takahashi, Utsunomiya-shi (JP)

Correspondence Address: Locke Lord Bissell & Liddell LLP;Attn: IP Docketing, Three World Financial Center, New York, NY, 10281-2101, US

(73) Assignee: CANON KABUSHIKI KAISHA, Tokyo (JP)

(21) Appl. No.: 12/338,272

(22) Filed: Dec. 18, 2008

(30) Foreign Application Priority Data
Dec. 28, 2007 (JP) 2007-341115

(51) Int. Cl. G03F 7/20; G03B 27/54

(52) U.S. Cl. 430/325; 355/70

(57) ABSTRACT

An exposure apparatus comprises an illumination optical system which illuminates an original, a light intensity distribution along a scanning direction of the original formed by the illumination optical system having a slope at a peripheral portion thereof, a projection optical system which projects a pattern of the original onto a substrate, an original stage which holds and scans the original, a substrate stage which holds and scans the substrate, one of the original and the substrate being scanned while the one of the original and the substrate is tilted with respect to an image plane of the projection optical system, and a control unit which controls the projection optical system so as to reduce an asymmetry of a light intensity distribution formed on a plane on which the substrate is located, due to the tilt of the one of the original and the substrate with respect to the image plane.

### BACKGROUND OF THE INVENTION

1. Field of the Invention

The present invention relates to an exposure apparatus and a device manufacturing method and, for example, to an exposure apparatus which exposes a substrate to light while an original or the substrate is tilted with respect to the image plane of a projection optical system, and a device manufacturing method of manufacturing a device using the same.

2. Description of the Related Art

In recent years, the rate of progress in the semiconductor device manufacturing technique is increasing more than ever. Along with this trend, the micropatterning is also making remarkable progress. In particular, the minimum feature size of a pattern formed by photolithography using an exposure apparatus has reached 100 nm or less.

To improve the resolving power, there are an approach of increasing the NA of the projection optical system, and an approach of shortening the wavelength of the exposure light from the g-line to the i-line and even to the oscillation wavelength of an excimer laser. These days, attempts are made to expand the limit of photolithography by using, for example, a phase shift mask and modified illumination.

Note that as the NA of the projection optical system is increased to improve the resolving power, the depth of focus decreases in inverse proportion to the square of the NA. For this reason, a process technique for ensuring a focus margin is required in the manufacture of semiconductor devices. On the other hand, the exposure apparatus is required to attain a technique for decreasing a focus error.

To increase the depth of focus, Japanese Patent Laid-Open No. 63-42122 proposes a technique of imaging the mask pattern at different positions in the optical axis direction, that is, the so-called FLEX technique.

Scanning exposure apparatuses have become a current mainstream along with a trend to reduce the degree of difficulty of lens design and to improve the stage control technique. A leading-edge scanning exposure apparatus mounts an immersion type lens having an NA that exceeds 1. Such an exposure apparatus including a projection lens having a high NA desirably implements the FLEX technique from the viewpoint of ensuring the depth of focus.

Japanese Patent No. 3255312 discloses a technique of moving the wafer in the optical axis direction while synchronously scanning the mask and the wafer.

The mask pattern is imaged on the substrate via the projection lens. Note that the light irradiation region on the mask surface and that on the wafer surface will be called the slit regions hereinafter. The slit regions have a rectangular or arcuated shape. In a normal exposure apparatus, the mask and the wafer hold a conjugate relationship across their entire slit regions, as shown in FIG. 9. In the exposure operation, the mask and wafer are scan-driven at a speed ratio matching the magnification of the projection lens.

The scanning exposure apparatus performs the FLEX exposure by scan-driving the mask or wafer so as to cross the object plane or image plane of the projection lens, as shown in FIG. 10. Although FIG. 10 shows a state in which the wafer is scan-driven while it is tilted with respect to the image plane, the mask may be scan-driven while it is tilted in place of the wafer in practice. To uniformly obtain an effect of the FLEX exposure across the entire image plane of the projection lens, a nearly rectangular slit region is necessary. If an arcuated slit region is used, the defocus amount changes for each position in a direction perpendicular to the scanning direction because of the tilt of the stage. This makes it impossible to uniformly obtain an effect of increasing the depth of focus in the shot region.

An excimer laser is currently mainly used as the light source of the scanning exposure apparatus. In scanning exposure apparatuses of the mirror projection scheme and step & scan scheme each of which uses an excimer laser which oscillates pulse light as the light source, exposure nonuniformity may occur on the mask surface or wafer surface as the scanning speed or pulse emission timing deviates from the original one. To avoid this exposure nonuniformity, Japanese Patent Laid-Open No. 7-230949 discloses a technique of inserting a field stop which defines the slit region at a position defocused from a plane conjugate to the mask to form a nearly trapezoidal light intensity distribution in the scanning direction of the mask. At positions corresponding to the slopes of the trapezoidal light intensity distribution, a certain component of the illumination light is shielded by the field stop. In this state, the effective light source (a portion having a light intensity higher than zero on the pupil plane of the illumination optical system) is eclipsed.

An exposure apparatus including an illumination optical system in which a field stop which defines the irradiation region is defocused from a plane conjugate to the mask surface suffers the following phenomenon. That is, the effective light source observed from the mask or wafer as the mask or wafer passes through the slopes of the trapezoid gradually is fully formed or eclipsed, like the wax and wane of the moon. As schematically shown in FIGS. 11A to 11C, when a certain point on the mask enters the slit region (a region in which light which illuminates the mask strikes the mask surface), the effective light source gradually appears from its peripheral portion when viewed from the certain point on the mask (FIG. 11A). When the certain point on the mask reaches the flat portion of the trapezoid representing the light intensity distribution, the entire effective light source appears when viewed from the certain point (FIG. 11B). When the certain point on the mask exits from the slit region, the effective light source is gradually eclipsed from its peripheral portion and finally disappears when viewed from the certain point on the mask (FIG. 11C). In this manner, as the effective light source shape observed from the mask changes, the incident angle of an effective chief ray from the illumination optical system changes with respect to the projection lens. That is, on the pupil plane of the projection lens as shown in FIGS. 12A to 12C, when a certain point on the mask enters the slit region (FIG. 12A), and when the certain point exits from the slit region (FIG. 12C), the effective chief ray of light which enters the certain point does not pass through the pupil center of the illumination optical system.

FIG. 13 is a graph illustrating the relationship between the defocused wavefront and the diffracted light when the effective light source shape has not changed. The abscissa indicates the coordinate position on the pupil, and the ordinate indicates the wavefront phase. When the effective light source has no distortion, the 0th-order diffracted light component passes through the center of the wavefront, and the ±1st-order diffracted light components travel in directions symmetrical about the 0th-order diffracted light component as the center. Letting P0, P1, and P2 be the phases of the 0th-, −1st-, and +1st-order diffracted light components, respectively, at this time, P1=P2. Then, we have:

(P1−P0)−(P2−P0)=P1−P2=0

Hence, when the effective light source has no distortion, no phase difference occurs so a light intensity distribution formed by the projection lens never becomes asymmetrical irrespective of the occurrence of defocus.

FIG. 14 is a graph illustrating the relationship between the defocused wavefront and the diffracted light when the effective light source shape has changed and then the 0th-order diffracted light component has shifted to the left. At this time, because P1≠P0, the phase difference is:

(P1−P0)−(P2−P0)=P1−P2=Dp≠0

In this case, a phase difference occurs in the defocused wavefront so a light intensity distribution formed by the projection lens becomes asymmetrical. The value Dp changes depending on the defocus amount; the larger the defocus amount, the larger the value Dp.

A case in which an apparatus including an illumination optical system as described above exposes a wafer W to light in accordance with the FLEX method will be considered. The wafer W is scan-driven obliquely with respect to the object plane (and the image plane) of a projection optical system PO so as to cross the center of the slit region. For this reason, while a certain point on a mask M passes through the slit region, the focus state of the certain point changes in the order of a state in which the certain point is defocused in the +Z direction, that in which the certain point matches a best focus position in the middle of the slit region, and that in which the certain point passes through the middle and exits from the slit region while being defocused in the −Z direction, as illustrated in FIG. 16. The telecentricity changes depending on the trapezoidal intensity distribution in the slit region in the order of a positive value on the slit front side (mask entrance side), zero in the middle, and a negative value on the slit rear side (mask exit side), as illustrated in FIG. 17.

Assuming that the state on the slit front side is as shown in FIG. 14, the state on the slit rear side is as shown in FIG. 15. In FIG. 15, the 0th-order diffracted light component shifts to a position symmetrical about the pupil center as compared with that shown FIG. 14. The phase difference at this time is:

(P1−P0)−(P2−P0)=P1−P2=Dp≠0

In this case, because the graphs shown in FIGS. 14 and 15 are symmetrical about the pupil center, the values Dp in FIGS. 14 and 15 have the same magnitude and sign. For this reason, the asymmetry of the light intensity distribution on the slit front side is in the same direction as that of the light intensity distribution on the slit rear side. In this case, the exposure amount profile in a certain minute region on the resist applied on the wafer is obtained by integrating the light intensity within the time taken for the minute region to pass through the slit region. Therefore, the obtained profile is an asymmetrical resist profile, as illustrated in FIG. 4. This resist profile has a characteristic as if the projection lens had coma aberration despite the fact that it has no coma aberration, resulting in a pattern defect.

### SUMMARY OF THE INVENTION

The present invention has been made in consideration of the above-described problem, and has as its object to provide a technique which can reduce the failures that may occur when, for example, a substrate is exposed to light while tilting an original or the substrate with respect to the image plane of a projection optical system.

According to the first aspect of the invention, there is provided an exposure apparatus comprising an illumination optical system which illuminates an original, a light intensity distribution along a scanning direction of the original formed by the illumination optical system having a slope at a peripheral portion thereof, a projection optical system which projects a pattern of the original onto a substrate, an original stage which holds and scans the original, a substrate stage which holds and scans the substrate, one of the original and the substrate being scanned while the one of the original and the substrate is tilted with respect to an image plane of the projection optical system, and a control unit which controls the projection optical system so as to reduce an asymmetry of a light intensity distribution formed on a plane on which the substrate is located, due to the tilt of the one of the original and the substrate with respect to the image plane.

According to the second aspect of the invention, there is provided a device manufacturing method comprising steps of exposing a substrate to light using an exposure apparatus as defined above, and developing the substrate.

According to the present invention, it is possible to provide a technique which can reduce the failures that may occur when, for example, a substrate is exposed to light while tilting an original or the substrate with respect to the image plane of a projection optical system.

Further features of the present invention will become apparent from the following description of exemplary embodiments with reference to the attached drawings.

### BRIEF DESCRIPTION OF THE DRAWINGS

FIG. 1 is a view showing the schematic arrangement of a scanning exposure apparatus according to the first embodiment of the present invention;

FIG. 2 is a flowchart illustrating an example of control by a control unit in the first embodiment of the present invention;

FIG. 3 is a view showing the schematic arrangement of a scanning exposure apparatus according to the second embodiment of the present invention;

FIG. 4 is a graph illustrating an asymmetry Id of the light intensity distribution (optical image);

FIG. 5 is a flowchart illustrating an example of control by a control unit in the second embodiment of the present invention;

FIG. 6 is a view schematically showing an asymmetry detection sensor and measurement pattern in scanning;

FIG. 7 is a view showing the schematic arrangement of a scanning exposure apparatus according to the third embodiment of the present invention;

FIG. 8 is a flowchart illustrating an example of control by a control unit in the third embodiment of the present invention;

FIG. 9 is a view schematically showing normal scanning exposure;

FIG. 10 is a view schematically showing scanning exposure by the FLEX method;

FIGS. 11A to 11C are views showing the relationship among the mask (original), the slit region, and the effective light source;

FIGS. 12A to 12C are views illustrating the effective light source shapes on the pupil plane of a projection lens;

FIG. 13 is a graph showing the wavefront and the diffracted light upon defocus when the effective light source shape has not changed;

FIG. 14 is a graph showing the wavefront and the diffracted light upon defocus when the effective light source shape has changed;

FIG. 15 is a graph showing the wavefront and the diffracted light upon defocus when the effective light source shape has changed;

FIG. 16 is a diagram illustrating a change in focus state in the slit region (illumination region); and

FIG. 17 is a diagram showing a change in telecentricity upon scanning.

### DESCRIPTION OF THE EMBODIMENTS

Embodiments of the present invention will be described below with reference to the accompanying drawings.

### First Embodiment

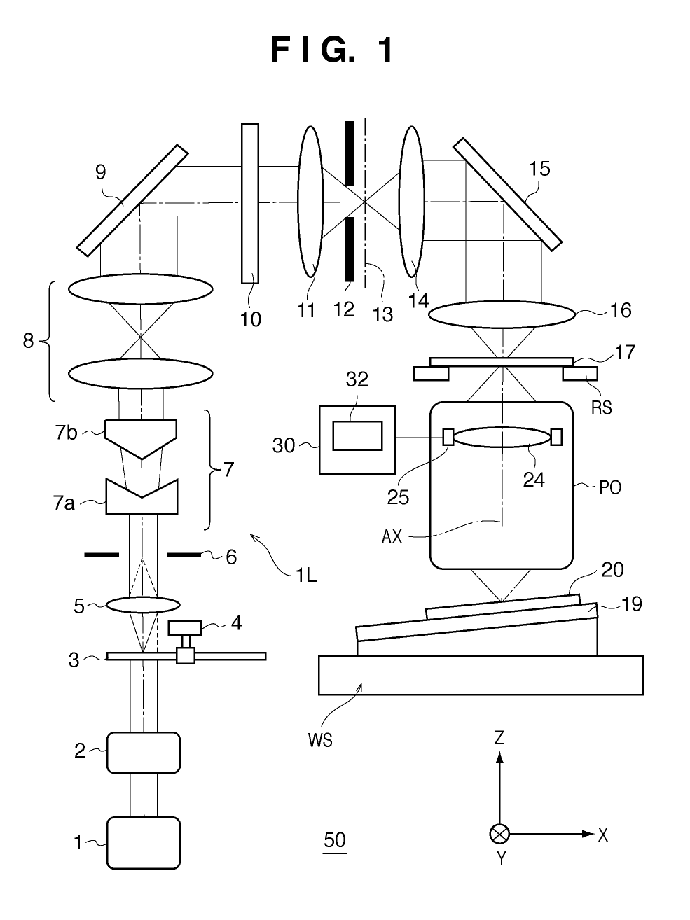

FIG. 1 is a view showing the schematic arrangement of a scanning exposure apparatus according to the first embodiment of the present invention. A scanning exposure apparatus 50 according to the first embodiment of the present invention scan-exposes a substrate 20 to light by projecting the pattern of an original (which can also be called a mask or reticle) 17 onto the substrate 20 by a projection optical system PO while scanning the original 17 and substrate 20.

This specification defines an X-Y-Z coordinate system assuming that an axis parallel to the optical axis of the projection optical system PO is the Z-axis, and an axis parallel to the scanning direction of the original 17 and substrate 20 is the X-axis. Directions parallel to the X-, Y-, and Z-axes are assumed to be the X, Y, and Z directions, respectively. Note that because the optical path of an illumination optical system IL is bent by mirrors 9 and 15, an X-Y-Z coordinate system for the illumination optical system IL is defined assuming that the optical axis of the illumination optical system IL is the Z-axis, and an axis corresponding to the scanning direction of the original 17 and substrate 20 is the X-axis.

In this embodiment, the illumination optical system IL includes elements inserted in the optical path from a light source 1 to a collimator lens 16. Examples of the light source 1 are an ArF excimer laser with an oscillation wavelength of about 193 nm, and a KrF excimer laser with an oscillation wavelength of about 248 nm. However, the present invention does not limit the type of light source and the wavelength of light emitted by the light source.

Light emitted by the light source 1 is guided to a diffraction optical element 3 by a light extension optical system 2. Typically, a plurality of diffraction optical elements 3 are inserted in a plurality of slots formed in a turret so that an arbitrary diffraction optical element 3 can be inserted into the optical path by an actuator 4.

The light which emerges from the diffraction optical element 3 is converged by a condenser lens 5 and forms a diffraction pattern on a diffraction pattern surface 6. Exchanging the diffraction optical element 3 inserted in the optical path with another one by the actuator 4 makes it possible to change the shape of the diffraction pattern.

Parameters such as the annular zone ratio and σ value of the diffraction pattern formed on the diffraction pattern surface 6 are adjusted by a prism group 7 including prisms 7a and 7b and a zoom lens 8, and the light beam which bears the information of the adjusted diffraction pattern strikes the mirror 9. The light beam reflected by the mirror 9 enters an optical integrator 10. The optical integrator 10 can be formed as, for example, a lens array (fly-eye lens).

The prism group 7 includes, for example, the prisms 7a and 7b. When the prisms 7a and 7b have a sufficiently short distance between them, they can be used as a single flat glass plate. The diffraction pattern formed on the diffraction pattern surface 6 undergoes σ value adjustment by the zoom lens 8 while maintaining an almost similar shape, and is imaged on the incident surface of the optical integrator 10. The annular zone ratio and angular aperture of the diffraction pattern formed on the diffraction pattern surface 6 are also adjusted by separating the positions of the prisms 7a and 7b.

The light beam which emerges from the optical integrator 10 is converged by a condenser lens 11 and forms a targeted light intensity distribution on a plane 13 conjugate to the original 17.

An illumination field stop (light-shielding member) 12 is inserted at a position shifted from the plane 13 conjugate to the plane on which the original 17 is located. The illumination field stop 12 defines the illumination region of the exposure light on the original 17, and controls the light intensity distribution in the illumination region. More specifically, the illumination field stop 12 controls the light intensity distribution of the exposure light so that the light intensity distribution along the scanning direction of the original 17 and substrate 20 has a shape (e.g., a trapezoidal shape or isosceles triangular shape) having slopes at its peripheral portions. A light intensity distribution with a shape having slopes at its peripheral portions is effective to reduce nonuniformity of the integrated exposure amount in the scanning direction due to the fact that light emitted by the light source 1 is pulse light, that is, has discontinuity.

The light beam having passed through the aperture (slit) of the illumination field stop 12 is reflected by the mirror 15 and illuminates the original 17. The pattern of the original 17 is projected by the projection optical system PO onto the substrate 20 held by a substrate stage WS including a tilt stage 19. With this operation, a latent image pattern is formed on the photosensitive agent applied on the surface of the substrate 20.

The tilt of the tilt stage 19 is controlled by a tilt mechanism (not shown) which aligns the substrate 20 held by the tilt stage 19 so that the substrate 20 is scanned while the surface of the substrate 20 is tilted with respect to the image plane of the projection optical system PO. The tilt of the substrate 20 can be detected by a sensor (not shown) and can be feedback-controlled. Note that the original 17 may be tilted in place of the substrate 20. In the example shown in FIG. 1, the scanning direction is a direction along the X-axis, and an axis along which the tilt of the substrate 20 or original 17 is controlled to increase the depth of focus is in the rotation direction about the Y-axis (ωY).

The projection optical system PO includes a driving mechanism 25 which changes the aberration of the projection optical system PO by moving, rotating, and/or deforming at least one lens 24 of a plurality of lenses which constitute the projection optical system PO. The driving mechanism 25 can include, for example, a mechanism which moves one or a plurality of lenses 24 in a direction along an optical axis AX of the projection optical system PO, and a mechanism which rotates one or a plurality of lenses 24 about an axis parallel to two axes (X- and Y-axes) perpendicular to the optical axis AX. The sensitivity of each lens 24 to a change in aberration upon driving it is determined by calculation or actual measurement in advance, and characteristic data (e.g., a table) representing this relationship is stored in a memory 32 of a control unit 30.

To approximate the aberration of the projection optical system PO to a target aberration, the control unit 30 performs calculation by referring to the characteristic data stored in the memory 32 so that the aberration to be adjusted comes close to the target aberration, and changes in other types of aberrations fall within allowances. On the basis of the calculation result, the control unit 30 determines the driving amounts of one or a plurality of lenses 24, and drives the one or plurality of lenses 24 in accordance with the determined driving amounts.

In substrate exposure by the FLEX method, the substrate 20 must be scan-driven so that the focus state of each point on the substrate 20 changes in the order of defocus→best focus→defocus on the side of the image plane of the projection optical system PO. For example, the control unit 30 controls the substrate stage WS so that a point, through which the optical axis AX passes, on the surface of the substrate 20 matches a best focus position of the projection optical system PO. Also, the control unit 30 controls the substrate stage WS so that a tilt amount θ of the substrate 20 becomes a targeted tilt amount. Because the tilt amount θ has a correlation with the defocus amount, it can be specified using the defocus amount. Note that the tilt amount θ of the substrate 20 and the defocus amount having a correlation with it are means for representing the tilt of the substrate 20.

Data representing the relationship between the tilt amount θ or defocus amount and the asymmetry (distortion amount) of the resist profile is obtained by simulation or experiment in advance, and stored in the memory 32. Also, data representing the relationship between the aberration (typically, the coma aberration) of the projection optical system PO and the asymmetry (distortion amount) of the resist profile is obtained by simulation or experiment in advance, and stored in the memory 32. Note that the coma aberration is a component which nearly uniformly changes in the slit region.

The control unit 30 determines the aberration change amount to correct the asymmetry (distortion amount) of the resist profile corresponding to the tilt of the substrate 20 (represented by, e.g., the tilt amount θ of the substrate 20 or the defocus amount). The control unit 30 drives one or a plurality of lenses 24 in accordance with the aberration change amount, thereby changing the aberration of the projection optical system PO. Also, manual setting of the aberration correction amount is preferably enabled assuming a case in which the results obtained by actual measurement and simulation do not match each other.

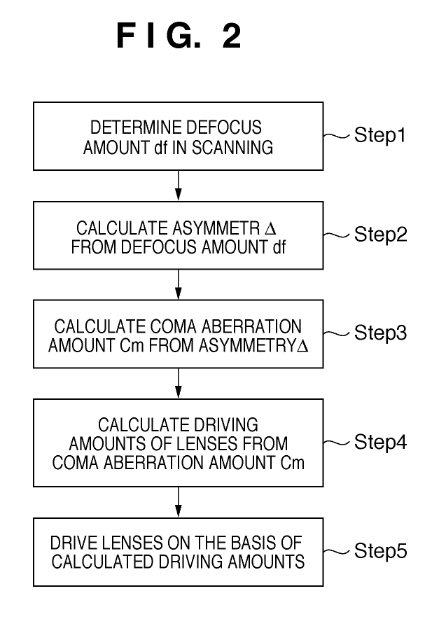

Control by the control unit 30 will be exemplified with reference to FIG. 2. In step 1, the control unit 30 determines a defocus amount df in scanning exposure in accordance with information (for example, a parameter representing a tilt amount θ or a parameter representing the defocus amount df itself) input from, for example, an external device or console.

In step 2, the control unit 30 calculates an asymmetry Δ of a resist profile (a light intensity distribution (optical image) formed on the surface of the substrate 20) corresponding to the defocus amount df in accordance with:

Δ=A×df (1)

where A is a coefficient for converting the defocus amount df into the asymmetry Δ, and is obtained by simulation or experiment in advance and stored in the memory 32.

In step 3, the control unit 30 calculates a coma aberration amount Cm necessary to correct the asymmetry, that is, the distortion Δ calculated in step 2, in accordance with:

Cm=B×Δ (2)

where B is a coefficient for converting the asymmetry Δ of the resist profile into the coma aberration amount Cm, and is obtained by simulation or experiment in advance and stored in the memory 32.

In step 4, the control unit 30 calculates the driving amounts of one or a plurality of lenses 24, which are necessary to generate the coma aberration amount Cm calculated in step 3. At this time, the driving amounts of the one or plurality of lenses 24 are determined by calculation of simultaneous equations or optimization calculation without changing other types of aberrations. In one example, matrices C representing the sensitivities of one or a plurality of lenses 24 to various types of aberrations can be obtained by simulation. Assume, for example, that driving amounts L1, L2, and L3 of three lenses 24 are calculated. Using the coma aberration amount Cm, a meridional image plane FC, and a magnification M as parameters, we have simultaneous equations:

Cm=C11×L1+C12×L2+C13×L3 (4)

FC=C21×L1+C22×L2+C23×L3 (5)

M=C31×L1+C32×L2+C33×L3 (6)

The driving amounts L1, L2, and L3 need only be obtained to satisfy FC=M=0.

If a larger number of types of aberrations are evaluated, for example, an evaluation function φ is defined by:

φ=√(G1×(S1×L1)²+G2×(S2×L2)²+G3×(S3×L3)²) (7)

where G1 to G3 are weighting functions, and S1 to S3 are matrices representing the sensitivities of the lenses to the aberrations.

The driving amounts L1 to L3 may be determined to minimize the evaluation function φ.

In step 5, the control unit 30 controls the driving mechanism 25 to drive the lenses 24 in accordance with the calculated driving amounts.

By the above-described control, the resist profile distorted due to illumination factors can be corrected by generating aberration in the projection optical system PO when exposure is performed by the FLEX method using the defocus amount df.

In this correction, if the conversion coefficients A and B are determined by simulation, an asymmetry obtained by simulation may not match an actual asymmetry. To remove this discrepancy, the conversion coefficients A and B may be manually changed or an offset term may be included in each equation.

### Second Embodiment

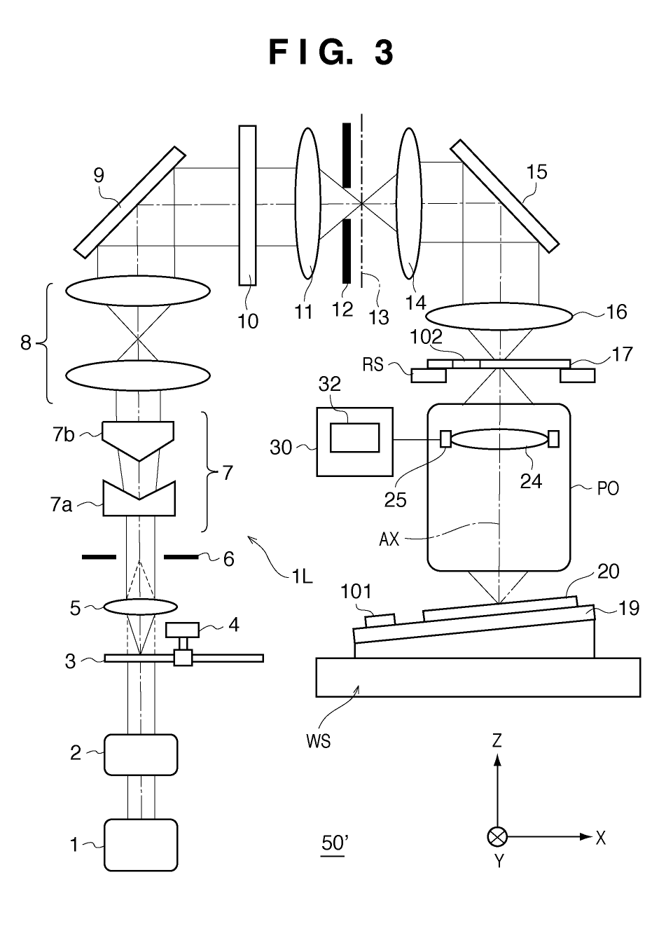

FIG. 3 is a view showing the schematic arrangement of a scanning exposure apparatus according to the second embodiment of the present invention. The same reference numerals as in the scanning exposure apparatus 50 according to the first embodiment shown in FIG. 1 denote the same constituent elements in FIG. 3. A scanning exposure apparatus 50′ according to the second embodiment shown in FIG. 3 is provided by adding an asymmetry detection sensor 101 and measurement pattern 102 to the scanning exposure apparatus 50 according to the first embodiment shown in FIG. 1. FIG. 6 is a view schematically showing the asymmetry detection sensor 101 and measurement pattern 102 in scanning.

The asymmetry detection sensor 101 can be arranged on a tilt stage 19 of a substrate stage WS. The measurement pattern 102 can be provided on an original 17 or an original stage RS which holds the original 17. The measurement pattern 102 may be provided at another position as long as it is on a plane conjugate to a substrate 20.

Control by a control unit 30 will be exemplified with reference to FIG. 5. In step 11, the control unit 30 determines a defocus amount df in scanning exposure in accordance with information (for example, a parameter representing a tilt amount θ or a parameter representing the defocus amount df itself) input from, for example, an external device or console.

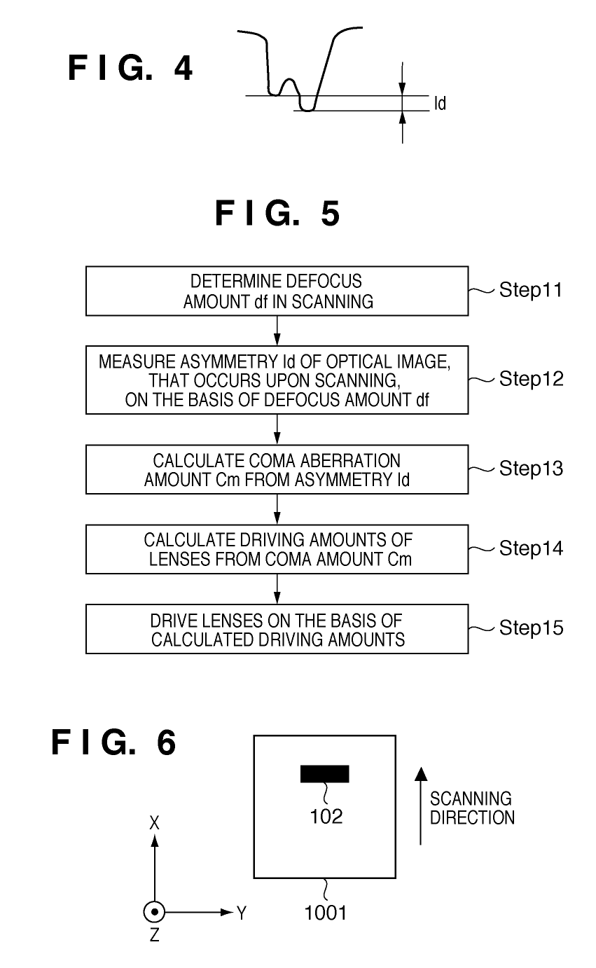

In step 12, the control unit 30 controls the tilt of the substrate stage WS (substrate 20) in accordance with the defocus amount df. Also, the control unit 30 controls the positions of the original stage RS and substrate stage WS to positions to start the detection of an image of the measurement pattern 102 by the asymmetry detection sensor 101. The control unit 30 controls the asymmetry detection sensor 101 to detect the light intensity distribution (optical image) of the measurement pattern 102 while scan-driving the original stage RS and substrate stage WS. This light intensity distribution (optical image) is equivalent to that which can be formed on the surface of the substrate 20 by the FLEX method. The control unit 30 determines an asymmetry Id by evaluating the asymmetry of this light intensity distribution. For example, the asymmetry Id can be determined as illustrated in FIG. 4.

In step 13, the control unit 30 calculates a coma aberration amount Cm necessary to correct the asymmetry Id calculated using the asymmetry detection sensor 101 in step 12, in accordance with:

Cm=Bi×Id (8)

where Bi is a coefficient for converting the asymmetry Id of the image of the measurement pattern 102 into the coma aberration amount Cm, and is obtained by simulation or experiment in advance and stored in a memory 32.

In step 14, the control unit 30 calculates the driving amounts of one or a plurality of lenses 24, which are necessary to generate the coma aberration amount Cm calculated in step 13. At this time, the driving amounts of the one or plurality of lenses 24 are determined by calculation of simultaneous equations or optimization calculation without changing other types of aberrations. In one example, matrices C representing the sensitivities of one or a plurality of lenses 24 to various types of aberrations can be obtained by simulation. Assume, for example, that driving amounts L1, L2, and L3 of three lenses 24 are calculated. Using the coma aberration amount Cm, a meridional image plane FC, and a magnification M as parameters, we have simultaneous equations:

Cm=C11×L1+C12×L2+C13×L3 (9)

FC=C21×L1+C22×L2+C23×L3 (10)

M=C31×L1+C32×L2+C33×L3 (11)

The driving amounts L1, L2, and L3 need only be obtained to satisfy FC=M=0.

If a larger number of types of aberrations are evaluated, for example, an evaluation function φ is defined by:

φ=√(G1×(S1×L1)²+G2×(S2×L2)²+G3×(S3×L3)²) (12)

where G1 to G3 are weighting functions, and S1 to S3 are matrices representing the sensitivities of the lenses to the aberrations.

The driving amounts L1 to L3 may be determined to minimize the evaluation function φ.

In step 15, the control unit 30 controls a driving mechanism 25 to drive the lenses 24 in accordance with the calculated driving amounts.

By the above-described control, the resist profile distorted due to illumination factors can be corrected by generating aberration in a projection optical system PO when exposure is performed by the FLEX method using the defocus amount df.

In this correction, if conversion coefficients A and B are determined by simulation, an asymmetry obtained by simulation may not match an actual asymmetry. To remove this discrepancy, the conversion coefficients A and B may be manually changed or an offset term may be included in each equation.

### Third Embodiment

FIG. 7 is a view showing the schematic arrangement of a scanning exposure apparatus according to the third embodiment of the present invention. The same reference numerals as in the scanning exposure apparatus 50 according to the first embodiment shown in FIG. 1 denote the same constituent elements in FIG. 7. In a scanning exposure apparatus 50″ according to the third embodiment shown in FIG. 7, a projection optical system PO includes a flat plate 42 which transmits exposure light and a driving mechanism 44 which drives the flat plate 42, as an aberration adjusting unit which generates a coma aberration amount Cm. The flat plate 42 is a plate member having parallel, upper and lower surfaces. The flat plate 42 is rotationally driven about an axis parallel to the Y-axis by the driving mechanism 44. In other words, the flat plate 42 has its surfaces (upper and lower surfaces) which can be tilted with respect to the image plane of the projection optical system PO. With this arrangement, only the coma aberration of the projection optical system PO can be controlled independently.

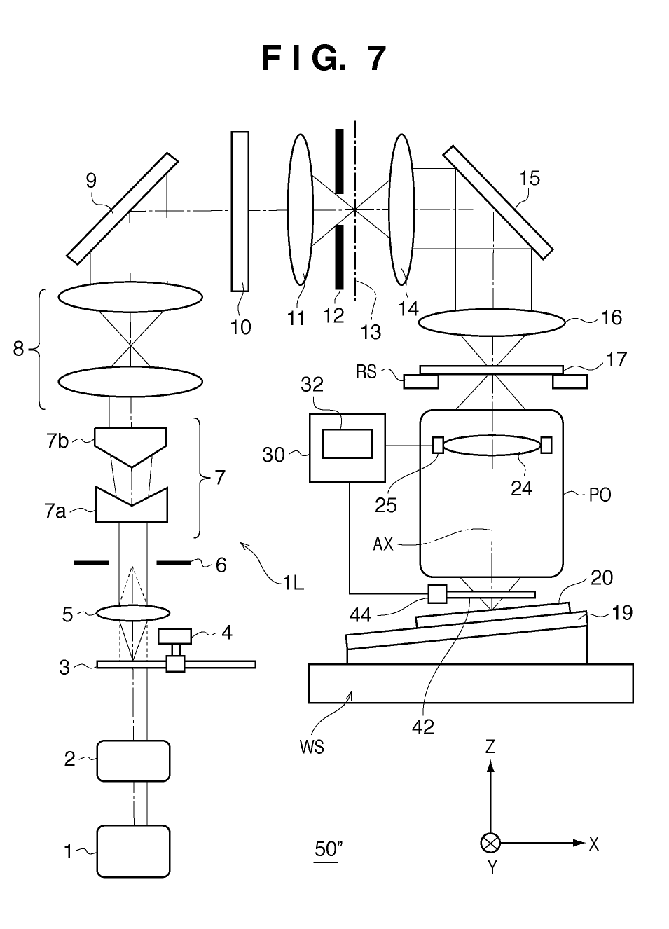

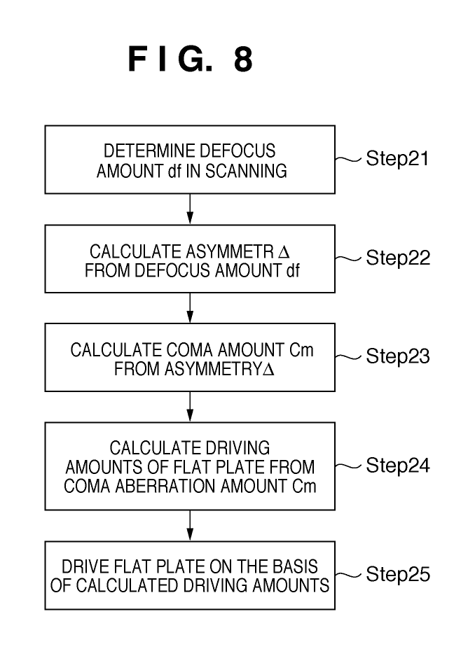

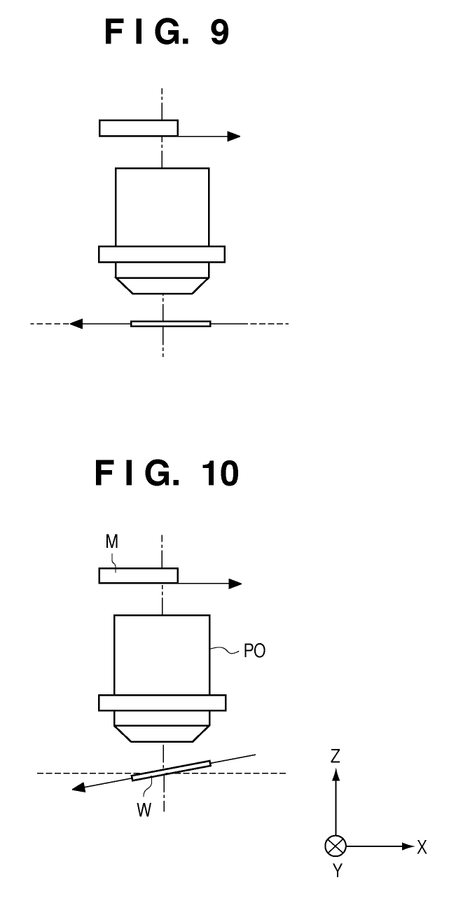

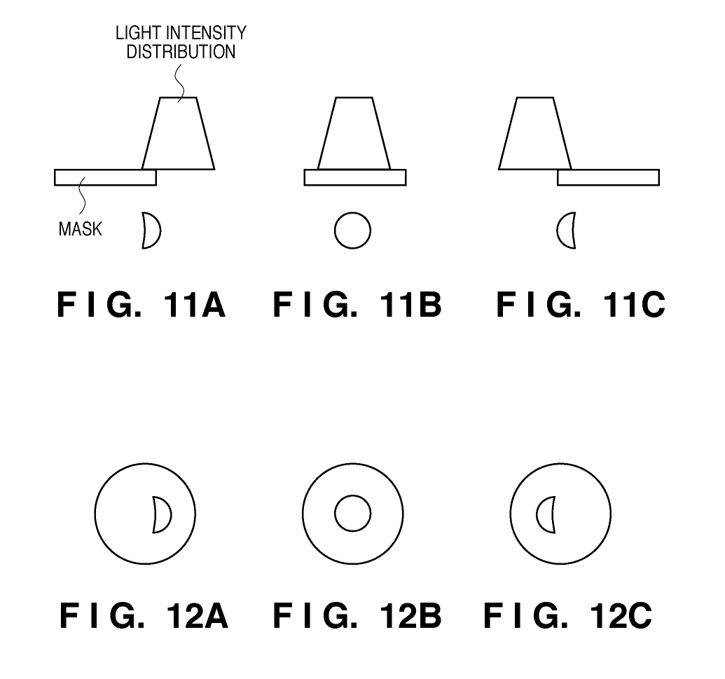

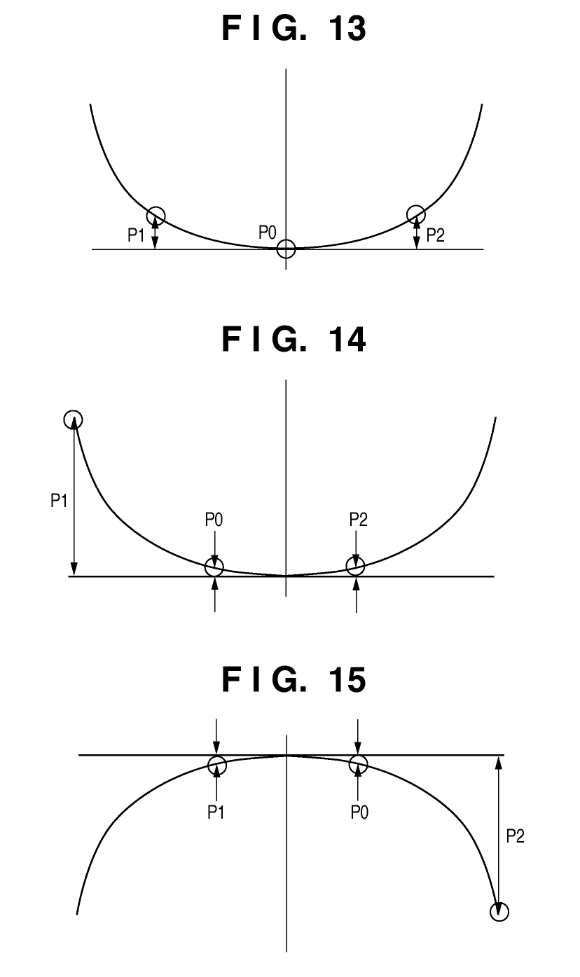

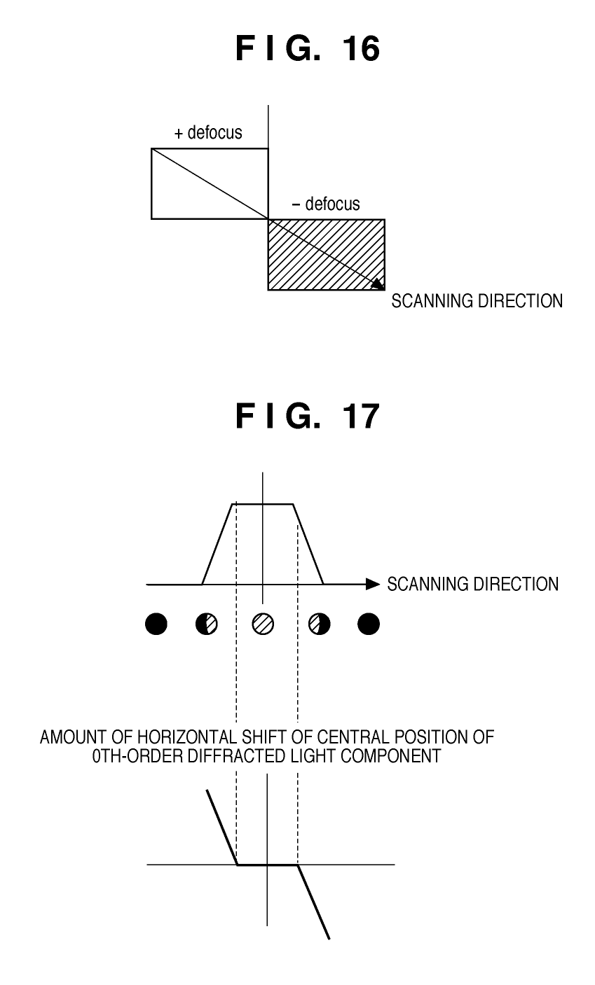

Control by a control unit 30 will be exemplified with reference to FIG. 8. In step 21, the control unit 30 determines a defocus amount df in scanning exposure in accordance with information (for example, a parameter representing a tilt amount θ or a parameter representing the defocus amount df itself) input from, for example, an external device or console.

In step 22, the control unit 30 calculates an asymmetry Δ of a resist profile corresponding to the defocus amount df in accordance with:

Δ=A×df (13)

where A is a coefficient for converting the defocus amount df into the asymmetry Δ, and is obtained by simulation or experiment in advance and stored in a memory 32.

In step 23, the control unit 30 calculates a coma aberration amount Cm necessary to correct the asymmetry, that is, the distortion Δ calculated in step 22, in accordance with:

Cm=B×Δ (14)

where B is a coefficient for converting the asymmetry Δ of the resist profile into the coma aberration amount Cm, and is obtained by simulation or experiment in advance and stored in the memory 32.

In step 24, the control unit 30 calculates a tilt amount (the rotation amount with respect to a surface parallel to the image plane) T of the flat plate 42, which is necessary to generate the coma aberration amount Cm calculated in step 23, in accordance with:

T=Bs×Cm (15)

where Bs is a coefficient for converting the coma aberration amount Cm into the tilt amount T of the flat plate 42, and is obtained by simulation or experiment in advance and stored in the memory 32.

In step 25, the control unit 30 controls the driving mechanism 44 to tilt the flat plate 42 in accordance with the calculated tilt amount T.

By the above-described control, the resist profile distorted due to illumination factors can be corrected by generating aberration in the projection optical system PO when exposure is performed by the FLEX method using the defocus amount df.

In this correction, if the conversion coefficients A and B are determined by simulation, an asymmetry obtained by simulation may not match an actual asymmetry. To remove this discrepancy, the conversion coefficients A and B may be manually changed or an offset term may be included in each equation.

### Other Embodiments

The above-described embodiments have been described assuming that a pattern asymmetry that occurs upon exposure by the FLEX method is adjusted by correcting the asymmetry of the resist profile. However, if characteristics other than the asymmetry of the resist profile are important factors of the pattern asymmetry, the coma aberration is adjusted by correcting them. For example, the coma aberration may be adjusted so as to correct characteristics, which are practically attributed to the asymmetry of the phase difference of the diffracted light, such as a difference in line width between two line patterns and the amount of shift of two or more patterns with different shapes.

Also, the coma aberration may be set so as to commonly improve two or more characteristics.

### APPLICATION EXAMPLE

A device manufacturing method according to a preferred embodiment of the present invention is suitable for the manufacture of devices such as a semiconductor device and liquid crystal device. This method can include a step of exposing a substrate coated with a photoresist to light by using an exposure apparatus, and a step of developing the exposed substrate. In addition, the device manufacturing method can include other known steps (e.g., oxidation, film forming, evaporation, doping, planarization, etching, resist removing, dicing, bonding, and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-341115, filed Dec. 28, 2007, which is hereby incorporated by reference herein in its entirety.

What is claimed is:

1. An exposure apparatus comprising:
an illumination optical system which illuminates an original, a light intensity distribution along a scanning direction of the original formed by said illumination optical system having a slope at a peripheral portion thereof;
a projection optical system which projects a pattern of the original onto a substrate;
an original stage which holds and scans the original;
a substrate stage which holds and scans the substrate, one of the original and the substrate being scanned while said one of the original and the substrate is tilted with respect to an image plane of said projection optical system; and
a control unit which controls said projection optical system so as to reduce an asymmetry of a light intensity distribution formed on a plane on which the substrate is located, due to the tilt of said one of the original and the substrate with respect to the image plane.

2. The apparatus according to claim 1, wherein said illumination optical system illuminates the original with light having a trapezoidal light intensity distribution along the scanning direction of the original.

3. The apparatus according to claim 1, wherein said control unit controls an aberration of said projection optical system so as to reduce an asymmetry of a light intensity distribution formed on a plane on which the substrate is located, due to the tilt of said one of the original and the substrate with respect to the image plane.

4. The apparatus according to claim 1, wherein said control unit controls a coma aberration of said projection optical system so as to reduce an asymmetry of a light intensity distribution formed on a plane on which the substrate is located, due to the tilt of said one of the original and the substrate with respect to the image plane.

5. The apparatus according to claim 1, wherein said control unit controls an aberration of said projection optical system by driving one or a plurality of lenses included in said projection optical system so as to reduce an asymmetry of a light intensity distribution formed on a plane on which the substrate is located, due to the tilt of said one of the original and the substrate with respect to the image plane.

6. The apparatus according to claim 1, wherein said control unit controls an aberration of said projection optical system by adjusting a tilt of a flat plate included in said projection optical system so as to reduce an asymmetry of a light intensity distribution formed on a plane on which the substrate is located, due to the tilt of said one of the original and the substrate with respect to the image plane.

7. The apparatus according to claim 1, further comprising:
a sensor which detects an asymmetry of a light intensity distribution formed on a plane on which the substrate is located,
wherein said control unit controls said projection optical system based on the asymmetry detected using said sensor.

8. The apparatus according to claim 1, wherein said control unit controls said projection optical system so as to reduce an asymmetry of an optical image formed on a plane on which the substrate is located, due to the tilt of said one of the original and the substrate.

9. A device manufacturing method comprising steps of:
exposing a substrate to light using an exposure apparatus; and
developing the substrate,
wherein the exposure apparatus comprising:
an illumination optical system which illuminates an original, a light intensity distribution along a scanning direction of the original formed by the illumination optical system having a slope at a peripheral portion thereof;
a projection optical system which projects a pattern of the original onto the substrate;
an original stage which holds and scans the original;
a substrate stage which holds and scans the substrate, one of the original and the substrate being scanned while the one of the original and the substrate is tilted with respect to an image plane of the projection optical system; and
a control unit which controls the projection optical system so as to reduce an asymmetry of a light intensity distribution formed on a plane on which the substrate is located, due to the tilt of the one of the original and the substrate with respect to the image plane.
